(19) United States
(12) Patent Application Publication
(10) Pub. No.: US 2011/0155237 A1
(43) Pub. Date: Jun. 30, 2011

(54) DYE-SENSITIZED SOLAR CELL

(76) Inventors: Noh-Jin Myung, Goyang (KR); Seong-Kee Park, Goyang (KR); Sung-Hoon Joo, Paju (KR); Seung-Hoon Ryu, Seoul (KR); So-Mi Jeong, Paju (KR)

(21) Appl. No.: 12/976,570

(22) Filed: Dec. 22, 2010

(30) Foreign Application Priority Data
Dec. 24, 2009 (KR) 10-2009-0131138

(51) Int. Cl. H01L 31/0224; H01L 51/44

(52) U.S. Cl. 136/256

(57) ABSTRACT

Disclosed is a dye-sensitized solar cell capable of improving fill factor of current, the solar cell including a first substrate and a second substrate, a first electrode formed on the first substrate, a second electrode formed on the second substrate to face the first electrode, an electrolyte interposed between the first and second electrodes, first and second electron collection metal lines formed between the first and second electrodes to collect electrons generated, passivation layers to shield the first and second electron collection metal lines, respectively, and a seal line formed on edge regions of the first and second substrates to bond the first and second substrates to each other and seal the electrolyte, wherein each of the passivation layers has a softening point higher than that of the seal line.

### CROSS-REFERENCE TO RELATED APPLICATION

Pursuant to 35 U.S.C. §119(a), this application claims the benefit of earlier filing date and right of priority to Korean Application No. 10-2009-0131138, filed on Dec. 24, 2009, the contents of which is incorporated by reference herein in its entirety.

### BACKGROUND OF THE INVENTION

1. Field of the Invention

The present invention relates to a dye-sensitized solar cell, and particularly, to a dye-sensitized solar cell, capable of minimizing softening of a passivation layer upon a seal line bonding process by forming the passivation layer of an electron collection metal line using glass frit with a softening point higher than that of the seal line.

2. Background of the Invention

A solar cell, which is capable of generating electricity without emitting a pollutant, thereby providing noteworthy solutions for the protection of environment and energy problems, is being watched with interest due to the exhaustion of fossil fuels and policies restricting carbon dioxide emissions.

A solar cell presented by Gratzel et al. from Switzerland in 1991 is a representative example of conventional dye-sensitized solar cells. The solar cell presented by Gratzel et al. is a photoelectrochemical solar cell using an oxide semiconductor composed of photosensitive dye molecules and titanium dioxide nanoparticles. The manufacturing costs of the solar cell are lower than silicon solar cells.

Currently available dye-sensitized solar cells include a nanoparticle oxide semiconductor cathode, a platinum anode, a dye coated on the cathode, an oxidation/reduction electrolyte using an organic solvent, and a transparent conductive layer.

However, in the structure of the dye-sensitized solar cell, when solar light is adsorbed onto the nanoparticle oxide semiconductor cathode, whose surface is chemically coated with the dye molecules, the dye molecules generate electron-hole pairs, and the electrons are injected into a conduction band of the semiconductor oxide. The electrons injected are transported into the transparent conductive layer through interfaces between nanoparticles so as to generate current. On the other hand, the holes generated from the dye molecules are reduced again by receiving the electrons due to the oxidation/reduction electrolyte, thereby completing the current generation process of the dye-sensitized solar cell.

However, the dye-sensitized solar cell in the structure has the following problems.

That is, in order to improve the current generation efficiency of the dye-sensitized solar cell, the area of the solar cell is increased to improve the generation efficiency of the electron-hole pairs by the dye molecules, and thereby the amount of electrons injected into the conduction band of the oxide semiconductor is increased, thereby increasing the amount of current transferred to the transparent conductive layer. However, the increase in the area of the solar cell gives rise to the increase in the area of the transparent conductive layer, which causes an increase in a sheet resistance of the transparent conductive layer, thereby degrading a fill factor of current generated.

### SUMMARY OF THE INVENTION

Therefore, to address of the above-identified problems, an aspect of the detailed description is to provide a dye-sensitized solar cell capable of enhancing a fill factor of current by forming an electron collection metal line.

Another aspect of the detailed description is to provide a dye-sensitized solar cell capable of minimizing a defect due to softening of glass frit during a bonding process, by virtue of forming a passivation layer for protecting an electron collection metal line using glass frit with a softening point higher than that of glass frit forming the seal line.

To achieve these and other advantages and in accordance with the purpose of the present invention, as embodied and broadly described herein, there is provided a dye-sensitized solar cell including a first substrate and a second substrate, a first electrode formed on the first substrate, a second electrode formed on the second substrate to face the first electrode, an electrolyte interposed between the first and second electrodes, first and second electron collection metal lines formed respectively at the first and second electrodes to collect electrons generated, passivation layers to shield the first and second electron collection metal lines, respectively, and a seal line formed on edge regions of the first and second substrates to bond the first and second substrates to each other and seal the electrolyte, wherein each of the passivation layers has a softening point higher than that of the seal line.

The first electrode may include a first transparent electrode, and a transition metal oxide layer formed on the first transparent electrode, and the second electrode may include a second transparent electrode, and a platinum layer formed on the second transparent electrode.

Each of the first and second transparent electrodes is composed of F-doped SnO₂ (FTO), Sn-doped In₂O₃, Indium Tin Oxide (ITO), SnO and ZnO, and the electrolyte may contain LiI, I₂, 1-hexyl-2,3-dimethylimidazolium iodiode and 4-tert-butylpyridine all dissolved in 3-methoxypropionitrile solvent.

Use of the electron collection metal lines can improve fill factor of current, and the passivation layers for protecting the electron collection metal lines may be formed of glass frit having a softening point higher than that forming the seal line, resulting in obviating a defect, which may be caused due to softening of the glass frit during a bonding process.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a sectional view showing a structure of a dye-sensitized solar cell in accordance with one exemplary embodiment;

FIG. 2 is a graph showing current densities of a dye-sensitized solar cell according to Example and a dye-sensitized solar cell according to Comparative Example 1; and

FIGS. 3A to 3D are graphs respectively showing characteristics of the dye-sensitized solar cell according to Example and a dye-sensitized solar cell according to Comparative Example 2.

### DETAILED DESCRIPTION OF THE INVENTION

Description will now be given in detail of a dye-sensitized solar cell according to the exemplary embodiments, with reference to the accompanying drawings. For the sake of brief description with reference to the drawings, the same or equivalent components will be provided with the same reference numbers, and description thereof will not be repeated.

This detailed description provides a dye-sensitized solar cell having improved current generation efficiency. Especially, a component for collecting electrons may separately be employed in addition to a transparent conductive layer, thus to enhance the current generation efficiency.

To this end, an electron collection metal line may be formed of a material with high conductivity such that current transferred to the transparent conductive layer can be carried to the electron collection metal line, thereby minimizing (eliminating) current intensity from being lowered due to a sheet resistance of the transparent conductive layer. Also, for protection of the electron collection metal line, a glass frit may be employed to surround (cover, shield) the electron collection metal line. The glass frit may have a softening point higher than that of a glass frit used for forming a seal line of the solar cell so as to obviate softening of a passivation layer during a bonding process.

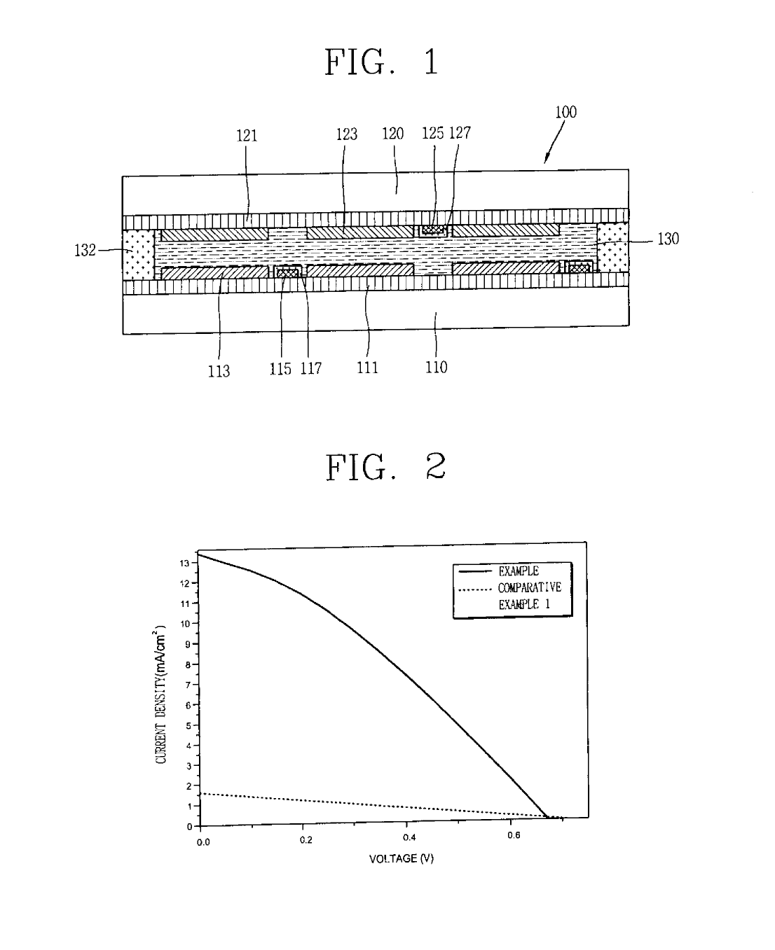

FIG. 1 is a sectional view showing a structure of a dye-sensitized solar cell in accordance with one exemplary embodiment.

As shown in FIG. 1, a dye-sensitized solar cell 100 in accordance with one exemplary embodiment may include first and second substrates 110 and 120 formed of a transparent material, a first transparent electrode 111 formed on the first substrate 110, a plurality of transition metal oxide layers 113 on the first transparent electrode 111, a second transparent electrode 121 on the second substrate 120, a plurality of platinum layers 123 formed on the second transparent electrode 121, a plurality of first electron collection metal lines 115 and second electron collection metal lines 125 formed on the first transparent electrode 111 and the second transparent electrode 121, respectively, a first passivation layer 117 and a second passivation layer 127 formed to shield the first and second electron collection metal lines 115 and 125, respectively, for protection thereof, a polymer electrolyte layer 130 formed between the first substrate 110 and the second substrate 120, and a seal line 132 formed at edge regions of the first and second substrates 110 and 120 to bond the first and second substrates 110 and 120 and seal the polymer electrolyte layer 130.

The first and second substrates 110 and 120 may be formed of a transparent material, such as plastic or glass, which may include one or more selected from a group consisting of polyethersulfone, polyacrylate, polyetherimide, polyethylene naphthalate, polyethylene terephthalate, polyphenylene sulfide, polyarylate, polyimide, polycarbonate, cellulose triacetate, and cellulose acetate propionate.

The first transparent electrode 111 and the second transparent electrode 121 are transparent metal oxide layers, examples of which may include F-doped SnO₂ (FTO), Sn-doped In₂O₃, Indium Tin Oxide (ITO), SnO, ZnO and the like.

The transition metal oxide layer 113 is a nano-oxide layer with a nano size of about 5 to 30 nm, and may be formed of a composition, which includes one or more types of metal oxides, selected from a group consisting of titanium dioxide (TiO₂), tin dioxide (SnO₂) and zinc oxide (ZnO).

Ruthenium complexes, which are able to adsorb visible rays, may preferably be used as the dye. Any dye can be used if it has the characteristics of improving efficiency by improving long wavelength absorption within visible rays and are capable of efficiently emitting electrons, can be used. For example, the dye may be one or a mixture of two or more selected from Xanthene dyes such as rhodamine B, rose Bengal, eosin, erythrocin and the like, cyanine dyes such as quinocyanine, cryptocyanine and the like, basic dyes such as phenosafranine, capri blue, tyocyn, methylene blue and the like, porphyrin-based compounds such as chlorophyll, zinc porphyrin, magnesium porphyrin and the like, other azo-based dyes, phthalocyanine compounds, anthraquinone dyes, polycyclic quinone-based dyes and the like.

The platinum layer 123 may be disposed to face the transition metal oxide layer 113 formed on the first substrate 110, and be a layer formed from a platinum catalyst, which functions to promote the reduction of electrolyte.

The polymer electrolyte layer 130 may be formed by using a solution, prepared by dissolving LiI, I₂, 1-hexyl-2,3-dimethylimidazolium iodiode and 4-tert-butylpyridine in 3-methoxypropionitrile as a solvent.

The first and second electron collection metal lines 115 and 125 may be formed of a metal with high conductivity, for example, argentums (Ag). The first and second electron collection metal lines 115 and 125 may be formed respectively on the first and second transparent electrodes 111 and 121 with predetermined widths by a preset interval therebetween. Since the first and second electron collection metal lines 115 and 125 have higher conductivities than those of the first and second transparent electrodes 111 and 121, electrons, which are injected into the conduction band of the transition metal oxide layer 113, are transported to the first transparent electrodes 111 and 121 through interfaces between nanoparticles, thereby generating current. Such current is then transported to an external circuit via the first and second electron collection metal lines 115 and 125.

As such, since the first and second electron collection metal lines 115 and 125 have the higher conductivities than those of the first and second transparent electrodes 111 and 121, even in case of the first and second transparent electrodes 111 and 121 having high sheet resistances, the current is transported to the external circuit via the first and second electron collection metal lines 115 and 125. Consequently, a loss of current due to the sheet resistances of the first and second transparent electrodes 111 and 121 may not occur, thereby remarkably improving the current generation efficiency of the solar cell 100.

The first passivation layer 117 and the second passivation layer 127 may be formed to shield the first and second electron collection metal lines 115 and 125 so as to protect the first and second electron collection metal lines 115 and 125 from the contact with the transition metal oxide layer 113 and the platinum layer 123, respectively.

The first and second passivation layers 117 and 127 may usually be made of glass frit. The glass frit may be one or a mixture of two or more selected from a group consisting of SiO₂—PbO based powder, SiO₂—PbO—B₂O₃ based powder and Bi₂O₃—B₂O₃—SiO₂ based powder. The glass frit may be prepared by producing SiO₂—PbO based powder, SiO₂—PbO—B₂O₃ based powder and Bi₂O₃—B₂O₃—SiO₂ based powder through fusion (melting), followed by grinding and micronization in a sequential manner. The glass frit may be produced in a slurry form by addition of filler, such as alkali oxide, and a polymer material, to be coated over the first and second electron collection metal lines 115 and 125 for shielding. The coated glass frit undergoes firing so as to create the first and second passivation layers 117 and 127. Also, the seal line 132 is produced using the glass frit.

Here, the glass frit forming the first and second passivation layers 117 and 127 and the glass frit forming the seal line 132 are composed of the same material, but their softening points are different. That is, the softening point of the glass frit forming the first and second passivation layers 117 and 127 is higher than that of the glass frit forming the seal line 132. Here, the softening point of the glass frit may be adjustable by controlling the ratio of alkali oxide contained in the glass frit.

The reason why the softening point of the first and second passivation layers 117 and 127 is higher than that of the seal line 132 is as follows. Typically, the glass frit of the seal line 132 is coated on at least one (e.g., 120) of the first and second substrates 110 and 120 and then the first and second substrates 110 and 120 are bonded to each other at temperature close to the softening point.

Accordingly, upon rising the temperature close to the softening point of the glass fit to bond the first and second substrates 110 and 120 to each other, if the softening point of the glass frit forming the first and second passivation layers 117 and 127 becomes similar to or lower than the softening point of the glass frit forming the seal line 132, the first and second passivation layers 117 and 127 are softened during the bonding process of the first and second substrates 110 and 120, thereby being destroyed. Consequently, the first and second electron collection metal lines 115 and 125 become contactable with the transition metal oxide layer 113 and the platinum layer 123, thereby losing an electron collection effect, namely, the function of transporting the current generated from the first and second electrodes 111 and 121 to the external circuit.

In the structure of the solar cell 100, as external light is incident on the transition metal oxide layer 113, the dye molecules adsorbed on the transition metal oxide layer 113 generate electron-hole pairs. The generated electrons are injected into the conduction band of the transition metal oxide layer 113. The electrons injected in the transition metal oxide layer 113 are then transported to the first transparent electrode 111 through interfaces between nanoparticles. Such electrons transported are then delivered to the external circuit via the first electron collection metal line 115 formed on the first transparent electrode 111, thereby generating current. Here, since the first electron collection metal line 115 is covered with the passivation layer 117, it may be protected from contact with the transition metal oxide layer 113.

Hereinafter, a method for producing a dye-sensitized solar cell according to an exemplary embodiment will be described in detail.

The conditions, for example, material, firing temperature, washing mechanism and the like, which will be illustrated in the following method, are for illustration only, without limiting the scope of present disclosure.

### Example

A first conductive glass substrate, for example, a transparent glass substrate coated with a transparent conductive layer (i.e., first transparent electrode) composed of F-doped SnO₂ (FTO), Sn-doped In₂O₃, Indium Tin Oxide (ITO), SnO and ZnO, was sliced into about 10 cm×10 cm size, followed by high-frequency sonication using a glass detergent for about 10 minutes, and washed with deionized water (DI). Afterwards, the washed glass substrate was washed with ethanol by the high-frequency sonication twice for about 15 minutes, completely rinsed with anhydrous ethanol, and dried in an oven at about 100° C.

For improving an adhesive with a transition metal oxide layer, for example, TiO₂, a conductive glass substrate was immersed in 40 mm of titanium (IV) chloride solution at 70□ for 40 minutes followed by washing using DI, and completely dried in an oven at about 100° C.

Afterwards, titania (TiO₂) paste was coated on the conductive glass substrate using a screen print or a mask. The coated TiO₂ paste was dried for about 20 minutes in an oven at about 100° C., which was repeated five times and then firing was performed for the conductive glass substrate for 60 minutes at 450° C., thereby forming a transition metal oxide layer (TiO₂) having a thickness of about 15 μm.

A silver paste was coated on the transition metal oxide layer, dried for 20 minutes at 100° C., and fired for 30 minutes at 450° C., thereby creating an electron collection metal line.

A glass frit paste whose softening point was 480° C. was coated on the electron collection metal line, and dried for 20 minutes at 150° C. A glass frit whose softening point was 430° C. was coated on an edge region of the glass substrate, and dried for 20 minutes at 50° C.

The glass frit paste coated on the electron collection metal line and the glass frit paste coated on the edge region of the substrate were fired for 20 minutes at 480□, thereby forming a passivation layer and a seal line.

A second conductive glass substrate, for example, a glass substrate coated with a transparent conductive layer composed of FTO, Sn-doped In₂O₃, ITO, SnO and ZnO, was sliced into about 10 cm×10 cm size, and holes for electrolyte injection were formed through the second conductive glass substrate by use of a diamond drill.

Afterwards, the second conductive glass substrate having the electrolyte injection holes underwent a high-frequency sonication using a glass detergent for about 10 minutes, washed with DI, and then washed off with ethanol by the high-frequency sonication twice for about 15 minutes. The resulting substrate was rinsed with anhydrous ethanol, and dried at about 100° C.

Hydrogen hexachloroplatinate (H₂PtCl₆)2-propanol solution was coated on the transparent conductive layer coated on the second conductive glass substrate, and fired for about 60 minutes at about 450° C., thereby creating a platinum layer.

A silver paste was deposited on the platinum layer, dried for 20 minutes at 100□, and fired for 30 minutes at 450□, thereby forming an electron collection metal line.

A glass frit having a softening point of 480° C. was coated on the electron collection metal line, and dried for 20 minutes at 150□. A glass frit having a softening point of 430□ was coated on an edge region of the glass substrate, and dried for 20 minutes at 50□.

The glass frit coated on the electron collection metal line and the glass frit coated on the edge region of the substrate were fired for 20 minutes at 480° C., thereby forming a passivation layer and a seal line.

The first conductive glass substrate and the second conductive glass substrate were aligned, fixed with clips having pressure of 1.5 kg/cm² at 430° C., and remained in the state for 30 minutes, thereby bonding the first and second conductive glass substrates to each other.

The bonded first and second conductive glass substrates were immersed in an anhydrous ethanol solution containing dyes of concentration of 0.5 mM for about 24 hours to adsorb the dyes, and dyes, which were not adsorbed using the anhydrous ethanol, were completely washed off to be dried in a vacuum oven.

An electrolyte was introduced through two electrolyte injection holes formed through the second conductive glass substrate. Afterwards, an electrolyte, which was prepared by dissolving 0.1M of LiI, 0.05M of I₂, 0.6M of 1-hexyl-2,3-demethylimidazolium iodiode and 0.5M of 4-tert-butylpyridine in 3-methoxypropionitrile solvent, was injected, and sealed with a surlyn strip and a cover glass, thereby completing production of the dye-sensitized solar cell.

### Comparative Example 1

A dye-sensitized solar cell was produced through the same processes except for processes 8 and 9 of Example.

At process 8, the glass frit was coated on the electron collection metal line, dried for 20 minutes at 150° C., and fired for 20 minutes at 480° C., thereby creating a passivation layer.

At process 9, surlyn, a polymer substance, was interposed between the first and second conductive glass substrates. The surlyn between the first and second conductive glass substrates was pressed using a hot press of 100-120° C., thereby bonding the first and second conductive glass substrates to each other.

### Comparative Example 2

A dye-sensitized solar cell was produced through the same processes except for processes 8 and 9 of Example.

At process 8, the glass frit having a softening point of 480□ was coated on the electron collection metal line, and dried for 20 minutes at 150□. A glass frit having a softening point of 480□ was coated on an edge region of the glass substrate, and dried for 20 minutes at 50□.

The glass frit coated on the electron collection metal line and the glass frit coated on the edge region of the substrate were fired for 20 minutes at 480° C., thereby forming a passivation layer and a seal line.

At process 9, the first conductive glass substrate and the second conductive glass substrate were aligned, fixed with clips having pressure of 1.5 kg/cm² at 480° C., and remained in the state for 30 minutes, thereby bonding the first and second conductive glass substrates to each other.

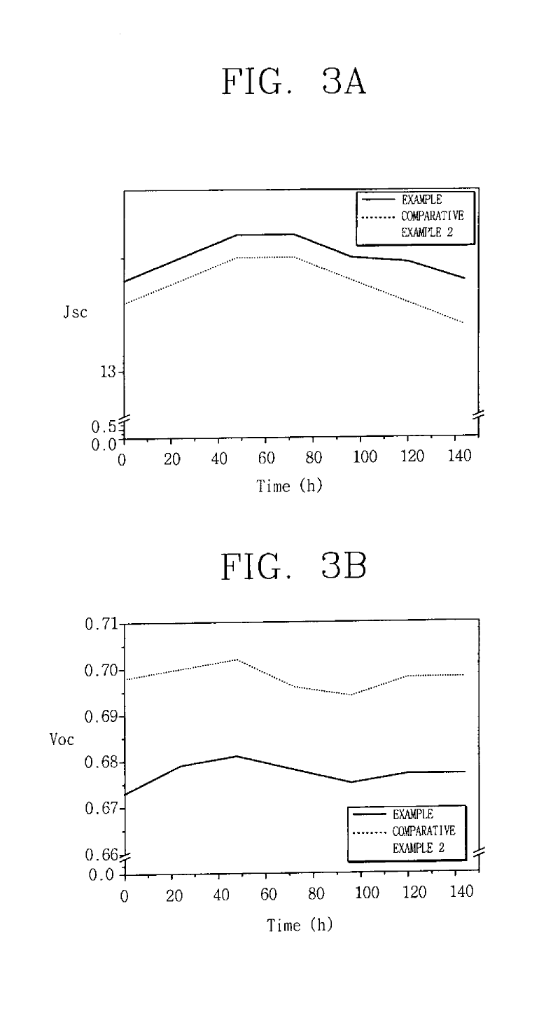

FIG. 2 is a graph showing current densities of the dye-sensitized solar cell according to Example and a dye-sensitized solar cell according to Comparative Example 1. Here, the difference between the dye-sensitized solar cell of Example and the dye-sensitized solar cell of Comparative Example 1 can be found in that the seal line is formed of the glass frit in Example, whereas the seal line is formed of the polymer substance such as surlyn in Comparative Example 1.

As shown in FIG. 2, the current density of the dye-sensitized solar cell of Example is significantly greater than that of Comparative Example 1. Especially, in a non-existence state of a short-circuit current, namely, an external resistance, which is significant in a solar cell, when light is emitted, the dye-sensitized solar cell of Example shows the current density of about 13.5 mA while the dye-sensitized solar cell of Comparative Example 1 shows the current density of merely 1.5 mA. Hence, it can be confirmed that the current generation efficiency of the dye-sensitized solar cell of Example (i.e., when the seal line is formed of the glass frit and the softening point of the glass frit of the passivation layer is higher than that of the polymer substance of the seal line) is much higher than that of the solar cell of Comparative Example 1 (i.e., when the seal line is formed of the polymer substance). In other words, use of the glass frit to form the seal line can more improve the current generation efficiency than use of polymer substance to form the seal line.

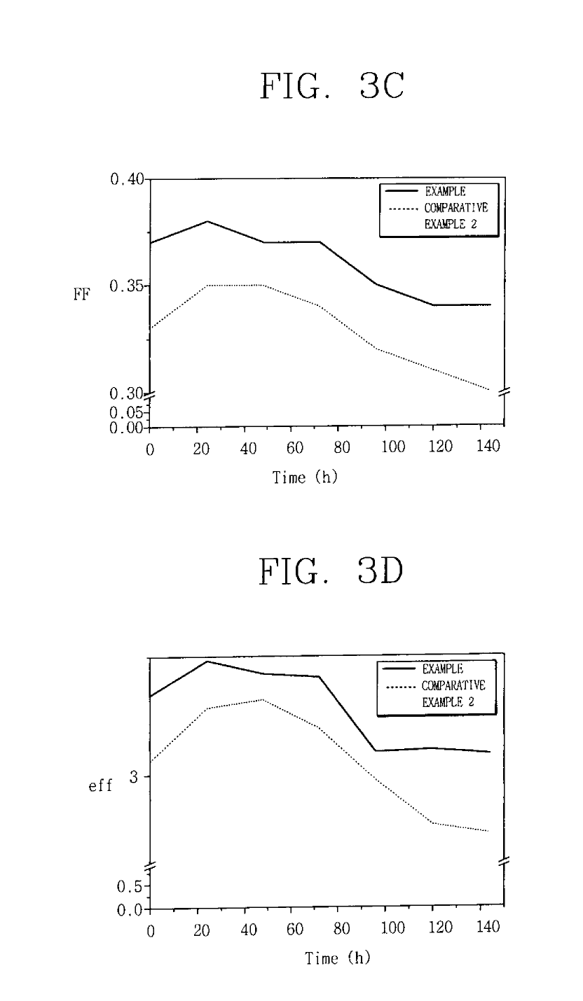

FIG. 3 shows characteristics of the dye-sensitized solar cell produced in Example and characteristics of the dye-sensitized solar cell produced in Comparative Example 2. FIG. 3A shows a short-circuit current (Jsc), FIG. 3B shows an open-circuit voltage (Voc), FIG. 3C shows a fill factor (FF), and FIG. 3D shows an efficiency (eff).

Here, the dye-sensitized solar cell of Example and that of Comparative Example 2 have the following difference. In Example, the softening point of the glass frit forming the passivation layer is 480□, the softening point of the glass frit forming the seal line is 430□, and the bonding process is performed at 430□. On the other hand, in Comparative Example 2, the glass frit of the passivation layer and that of the seal line have the same softening point of 480□ and the bonding process is performed at 480□. In other words, in Example, the softening point of the glass frit of the passivation layer is higher than the bonding temperature, so the passivation layer may not be softened during the bonding process. On the contrary, in Comparative Example 2, the softening point of the glass frit of the seal line is similar to the bonding temperature, which may cause the passivation layer to be softened during the bonding process.

Referring to FIGS. 3A to 3D, comparing the dye-sensitized solar cell of Example with the dye-sensitized solar cell of Comparative Example 2, it can be noticed that the overall characteristics of the dye-sensitized solar cell of Example have been improved. That is, when light is emitted without any external resistance, the dye-sensitized solar cell of Example has high current density (Jsc). Also, in regard of the voltage (Voc) applied to both ends of the solar cell in an open-circuit state, the voltage (Voc) of Example is higher than that of Comparative Example 2.

In addition, it has been confirmed that not only the fill factor (FF) but also the efficiency (eff) of the dye-sensitized solar cell of Example are higher than those of Comparative Example 2.

As such, the dye-sensitized solar cell according to the present disclosure employs the passivation layers and the seal line both formed of the glass frit, and allows the glass frit of the passivation layers to have higher softening point than that of the glass frit of the seal line, thereby protecting the passivation layers from being softened during the bonding process, resulting in remarkable improvement of current generation efficiency.

The foregoing embodiments and advantages are merely exemplary and are not to be construed as limiting the present disclosure. The present teachings can be readily applied to other types of apparatuses. This description is intended to be illustrative, and not to limit the scope of the claims. Many alternatives, modifications, and variations will be apparent to those skilled in the art. The features, structures, methods, and other characteristics of the exemplary embodiments described herein may be combined in various ways to obtain additional and/or alternative exemplary embodiments.

As the present features may be embodied in several forms without departing from the characteristics thereof, it should also be understood that the above-described embodiments are not limited by any of the details of the foregoing description, unless otherwise specified, but rather should be construed broadly within its scope as defined in the appended claims, and therefore all changes and modifications that fall within the metes and bounds of the claims, or equivalents of such metes and bounds are therefore intended to be embraced by the appended claims.

What is claimed is:

1. A dye-sensitized solar cell comprising:
a first substrate and a second substrate;
a first electrode formed on the first substrate;
a second electrode formed on the second substrate to face the first electrode;
an electrolyte interposed between the first and second electrodes;
first and second electron collection metal lines formed respectively at the first and second electrodes to collect electrons generated;
passivation layers to shield the first and second electron collection metal lines, respectively; and
a seal line formed on edge regions of the first and second substrates to bond the first and second substrates to each other and seal the electrolyte,
wherein each of the passivation layers has a softening point higher than that of the seal line.

2. The dye-sensitized solar cell of claim 1, wherein the first electrode comprises:
a first transparent electrode; and
a transition metal oxide layer formed on the first transparent electrode.

3. The dye-sensitized solar cell of claim 2, wherein the first transparent electrode is composed of F-doped SnO₂ (FTO), Sn-doped In₂O₃, Indium Tin Oxide (ITO), SnO and ZnO.

4. The dye-sensitized solar cell of claim 1, wherein the second electrode comprises:
a second transparent electrode; and
a platinum layer formed on the second transparent electrode.

5. The dye-sensitized solar cell of claim 4, wherein the second transparent electrode is composed of F-doped SnO₂ (FTO), Sn-doped In₂O₃, Indium Tin Oxide (ITO), SnO and ZnO.

6. The dye-sensitized solar cell of claim 1, wherein the electrolyte contains LiI, I₂, 1-hexyl-2,3-dimethylimidazolium iodiode and 4-tert-butylpyridine all dissolved in 3-methoxypropionitrile solvent.

7. The dye-sensitized solar cell of claim 1, wherein the first and second electron collection metal lines are formed of argentums (Ag).

8. The dye-sensitized solar cell of claim 1, wherein the passivation layer and the seal line are made of glass frit containing alkali oxide.

9. The dye-sensitized solar cell of claim 8, wherein the passivation layer has a softening point of 480° C. and the seal line has a softening point of 430° C.

10. The dye-sensitized solar cell of claim 8, wherein the softening point of the glass frit differs according to an addition amount of alkali oxide.
